(19) United States
(12) Patent Application Publication
(10) Pub. No.: US 2011/0247548 A1
(43) Pub. Date: Oct. 13, 2011

(54) Method For Fabricating Of ZnO Particle And Method For Fabricating Of ZnO Rod

(75) Inventors: Gun-Young JUNG, Buk-Gu (KR); Ki-Seok KIM, Buk-Gu (KR)

(73) Assignee: GWANGJU INSTITUTE OF SCIENCE AND TECHNOLOGY, Gwangju-city (KR)

(21) Appl. No.: 13/085,072

(22) Filed: Apr. 12, 2011

Related U.S. Application Data
(60) Provisional application No. 61/323,039, filed on Apr. 12, 2010.

(51) Int. Cl. C30B 7/14; C30B 19/00

(52) U.S. Cl. 117/58; 117/68

(57) ABSTRACT

Disclosed herein are a method for preparing zinc oxide (ZnO) nanoparticles and a method for preparing ZnO nanorods. The method for preparing ZnO nanoparticles may include: preparing a growth solution containing a zinc salt, a precipitator, and a growth inhibitor; and applying heat to the growth solution to prepare ZnO nanoparticles. Moreover, the method for preparing ZnO nanorods may include: forming a ZnO seed layer on a substrate; forming a pattern layer including a plurality of holes on the ZnO seed layer; preparing a growth solution containing a zinc salt, a precipitator, and a growth inhibitor; and immersing the substrate including the pattern layer in the growth solution such that ZnO nanorods are grown in the holes.

### PRIORITY STATEMENT

This application claims priority under 35 U.S.C. §119(e) to provisional U.S. patent application No. 61/323,039, filed on Apr. 12, 2010, the entire contents of which are herein incorporated by reference.

### BACKGOUND OF THE INVENTION

1. Field of the Invention

The present invention relates to a method for preparing zinc oxide (ZnO) and, more particularly, to a method for preparing ZnO nanoparticles and a method for preparing ZnO nanorods.

2. Description of Related Art

One-directional nano-sized materials such as nanorods, nanowires, etc. have been extensively studied in electronic or optoelectronic engineering due to their intrinsic optical and electrical properties.

Among them, zinc oxide (ZnO) has attracted much attention because it has excellent properties such as near-UV radiation and piezoelectricity as well as a band gap energy of 3.37 eV and a large exciton binding energy of 60 meV.

However, according to a conventional method for preparing nanorods, it is difficult to control the distance between nanorods and the alignment of nanorods, and it is also difficult to ensure the uniformity of the diameter of the nanorods.

### SUMMARY OF THE INVENTION

Accordingly, the present invention has been made in an effort to solve the above-described drawbacks, and an object of the present invention is to provide a method for preparing zinc oxide (ZnO) nanoparticles and a method for preparing ZnO nanorods, which can control the distance between ZnO nanorods and the alignment of the ZnO nanorods and ensure the uniformity of the diameter.

In an aspect, the present invention provides a method for a method for preparing zinc oxide (ZnO) nanoparticles, the method including: preparing a growth solution containing a zinc salt, a precipitator, and a growth inhibitor; and applying heat to the growth solution to prepare ZnO nanoparticles.

The zinc salt may be zinc acetate, zinc nitrate, zinc sulfate, or zinc chloride.

The precipitator may be NaOH, Na2CO₃, LiOH, H₂O₂, KOH, or NH₄OH.

The growth inhibitor may be a cationic polymer.

The growth inhibitor may have a hyperbranched structure.

The growth inhibitor may be a polymer having an amine group.

The growth inhibitor is polyethyleneimine.

In another aspect, the present invention provides a method for preparing zinc oxide (ZnO) nanorods, the method including: forming a ZnO seed layer on a substrate; forming a pattern layer including a plurality of holes on the ZnO seed layer; preparing a growth solution containing a zinc salt, a precipitator, and a growth inhibitor; and immersing the substrate including the pattern layer in the growth solution such that the ZnO nanorods are grown in the holes.

The ZnO seed layer may be formed by producing ZnO nanoparticles by a hydrothermal synthesis method, a sol-gel method, or a reduction method and spin-casting the ZnO nanoparticles.

The ZnO seed layer may be formed by metal organic chemical vapor deposition (MOCVD), evaporation, or sputtering.

The zinc salt may be Zn(NO₃)₂.H₂O, C₄H₆O₄Zn.2H₂O, or ZnSO₄.7H₂O.

The precipitator may be C₆H₁₂N₄, NaOH, or KOH.

The growth inhibitor may be a cationic polymer.

The growth inhibitor may have as a hyperbranched structure.

The growth inhibitor may be a polymer having an amine group.

The growth inhibitor may be polyethyleneimine.

The growth inhibitor may be added in an amount of 0.5 to 1 M with respect to 1 M of the zinc salt.

The growth solution may have a pH of 9 to 11.

### BRIEF DESCRIPTION OF THE DRAWINGS

FIGS. 1A to 1D are schematic diagrams showing a method for preparing single-crystal ZnO nanorods according to an exemplary embodiment of the present invention;

FIG. 2A is an SEM image of ZnO nanoparticles prepared in Preparation Example 1;

FIG. 2B is an XRD graph of ZnO nanoparticles prepared in Preparation Example 1;

FIG. 3 shows SEM images of ZnO nanorods prepared in Preparation Examples 1 to 5; and

FIG. 4 shows SEM images of ZnO nanorods prepared according to an exemplary embodiment of the present invention.

### DETAILED DESCRIPTION OF THE INVENTION

Hereinafter, preferred embodiments in accordance with the present invention will be described with reference to the accompanying drawings. It should be appreciated that the invention is not limited to the specific embodiments, but covers all modifications, equivalents, and alternatives falling within the spirit and scope of the invention as defined by the claims. In the drawings, the same elements will be designated by the same reference numerals and their descriptions will be omitted

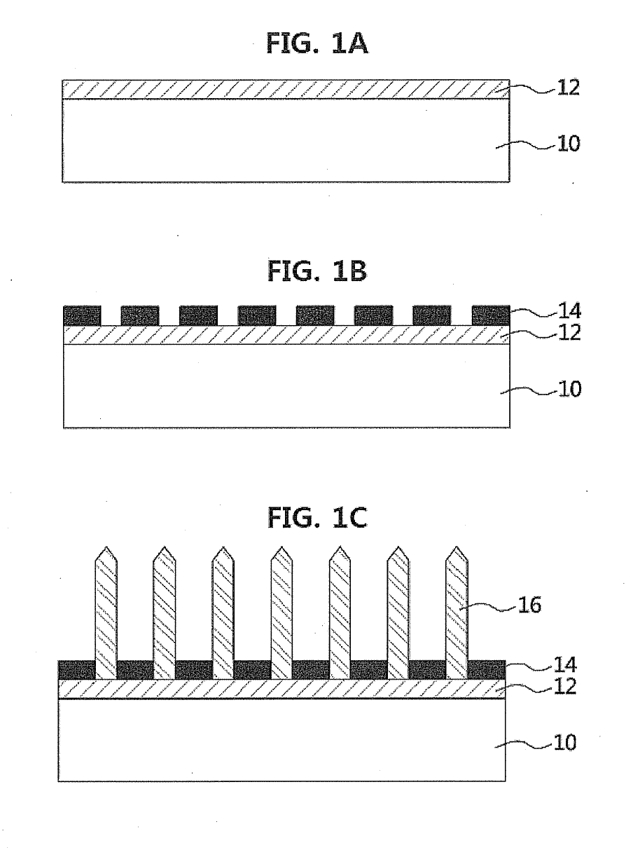

FIGS. 1A to 1D are schematic diagrams showing a method for preparing ZnO nanorods according to an exemplary embodiment of the present invention.

Referring to FIG. 1A, a seed layer 12 may be formed on a substrate 10.

The substrate 10 may be a glass substrate, an Al₂O₃ substrate, an ITO substrate, a Si substrate, a GaN substrate, a SiC substrate, a ZnO substrate, a GaAs substrate, an InP substrate, an AlN substrate, a ScAlMgO4 substrate, or a LiNbO₃ substrate. The substrate 10 may be washed with isopropyl alcohol (IPA) or distilled water before use.

The seed layer 12 may be a zinc oxide (ZnO) nanoparticle layer comprising nanoparticles having a uniform particle size. For example, when the ZnO nanoparticle layer is formed by a hydrothermal synthesis method, a growth solution containing a first zinc salt solution, a first precipitation solution, and a first growth inhibitor may be prepared.

The solutions may be prepared by dissolving a first zinc salt and a first precipitator in a polar solvent, respectively. The first zinc salt may be zinc acetate, zinc nitrate, zinc sulfate, or zinc chloride, and the first precipitator may be NaOH, Na₂CO₃, LiOH, H₂O₂, KOH, or NH₄OH. The polar solvent may contain water, alcohol, or an organic solvent. Preferably, the polar solvent may contain both water and alcohol.

The ZnO nanoparticles may be prepared by applying heat to the growth solution. The application of heat may be performed in the temperature of 50 to 100° C. at atmospheric pressure for 1 to 2 hours.

The reaction mechanism of the ZnO nanoparticles may be represented by the following formulas 1 to 5. In detail, when the first zinc salt solution and the first precipitation solution are mixed together, Zn²⁺ in the first zinc salt solution and OH⁻ in the first precipitation solution may produce Zn(OH)₂ as an intermediate by the following formula 1. When heat is applied to the mixed solution, the Zn(OH)₂ may be decomposed into Zn²⁺ and OH⁻ by the following formula 2.

When the concentration of Zn²⁺ and OH⁻ is increased by continuous decomposition, a ZnO core may be formed by a condensation reaction represented by the following formula 3. At the same time, a ZnO growth factor, Zn(OH)₂, may be produced by the following formula 4. Subsequently, the ZnO growth factor, Zn(OH)₂, may react with the ZnO core to produce a ZnO nanoparticle by the following formula 5.

Zn²⁺+2OH⁻ [symbol] Zn(OH)₂ [Formula 1]

Zn(OH)₂ [symbol] Zn²⁺+2OH⁻ [Formula 2]

Zn²⁺+2OH⁻→ZnO+H₂O [Formula 3]

Zn(OH)₂+2OH⁻→Zn(OH)₄²⁻ [Formula 4]

Zn(OH)₄²⁻→ZnO+H₂O+2OH⁻ [Formula 5]

The first growth inhibitor is added to the solution containing the ZnO nanoparticles, and the resulting solution is refluxed with a rotary evaporator to inhibit the overgrowth of the ZnO nanoparticles.

The first growth inhibitor may be a cationic polymer. In detail, the cationic polymer may be a polymer having an amine group such as polyethyleneimine (PEI) having high solubility in a polar solvent, for example. The cationic polymer may have a hyperbranched structure. Therefore, the growth factors containing anions, Zn(OH)₄²⁻, are bonded to the cations present in the branches of the polymer and do not participate in the growth of the ZnO cores, thereby preventing the ZnO nanoparticles from being overgrown.

The diameter of the ZnO nanoparticles can be controlled by adjusting the concentration of the first growth inhibitor. That is, when the concentration of the first growth inhibitor becomes higher, the diameter of the ZnO nanoparticles may be reduced.

The ZnO nanoparticles may be separated from the solutions. The ZnO nanoparticles may be separated by a centrifugal separator, and the separated ZnO nanoparticles may be washed with alcohol. The resulting ZnO nanoparticles are dried to yield the final ZnO nanoparticles. The drying may be carried out at a temperature of about 70° C.

The ZnO nanoparticles prepared in the above manner are prevented from being overgrown by the first growth inhibitor, and thus it is possible to produce the ZnO nanoparticles having a uniform shape. The ZnO nanoparticles may have a nano size, for example, a size of 3 to 5 nm.

The seed layer 12 may be formed by dispersing the thus prepared ZnO nanoparticles in a solvent and spin-casting the ZnO nanoparticles in a solvent. The solvent may be a polar solvent. The polar solvent may be ethanol, isopropyl, alcohol, water, or distilled water. Preferably, the polar solvent may contain both water and ethanol.

Alternatively, the seed layer 12 may be formed by producing the ZnO nanoparticles by a sol-gel method or a reduction method and spin-casting the ZnO nanoparticles in a solvent. Moreover, the seed layer 12 may be directly formed by evaporation, metal organic chemical vapor deposition (MOCVD), or sputtering.

Referring to FIG. 1b, a pattern layer 14 having a plurality of holes may be formed on the seed layer 12. The pattern layer 14 may be an organic or inorganic pattern layer. The organic pattern layer may be a resist layer such as a poly(methyl methacrylate) (PMMA) layer, an epoxy layer, etc. The organic pattern layer may be formed by forming the resist layer on the seed layer 12 by spin-coating and then patterning the resist layer by lithography. The inorganic pattern layer may be an inorganic layer such as a silicon oxide (SiO₂) layer, a silicon nitride (Si₃N₄) layer, or a silicon layer. The inorganic pattern layer may be formed by forming the inorganic layer on the seed layer 12 and then patterning the inorganic layer by lithography or etching. The lithography may be nanoimprint lithography, laser interference lithography, electron beam lithography, ultraviolet lithography, holographic lithography, or immersion lithography.

Referring to FIG. 1C, ZnO nanorods 16 may be formed in the holes of the pattern layer 14. Preferably, a single ZnO nanorod 16 may be formed in each hole of the pattern layer 14. The ZnO nanorod may have a nano size.

The ZnO nanorods 16 may be formed by a hydrothermal synthesis method. When the ZnO nanorods formed by the hydrothermal synthesis method, for example, a growth solution containing a second zinc salt solution, a second precipitation solution, and a second growth inhibitor may be prepared.

After the substrate 10 with the pattern layer 14 is immersed in the growth solution, heat may be applied thereto. The application of heat may be performed in the temperature of 50 to 100° C.

The second zinc salt solution may be Zn(NO₃)₂.H₂O, C₄H₆O₄Zn.2H₂O, or ZnSO₄.7H₂O. The second precipitation solution may be C₆H₁₂N₄, NaOH, or KOH, and preferably C₆H₁₂N₄. The C₆H₁₂N₄ can produce NH⁴⁺ and OH⁻, which are the growth factors for forming the ZnO nanorods and, since the growth rate and the OH⁻ concentration can be easily controlled, the reaction rate can be controlled.

The second growth inhibitor may be a cationic polymer. In detail, the cationic polymer may be a polymer having an amine group such as polyethyleneimine (PEI) having high solubility in a polar solvent.

The reaction mechanism of the ZnO nanorods may be described by the following formulas 6 to 12. Hexamine (C₆H₁₂N₄) used as the second precipitator may produce NH⁴⁺ and OH⁻ by the following formulas 6 and 7. Moreover, Zn(NO₃)₂ used as the second zinc salt solution may produce zinc ions by the following formula 8.

C₆H₁₂N₄+6H₂O [symbol] 6CH₂O+4NH₃ [Formula 6]

NH₃+H₂O [symbol] NH⁴⁺+OH⁻ [Formula 7]

Zn(NO₃)₂→Zn²⁺+2NO³⁻ [Formula 8]

4NH₃, OH⁻, and Zn²⁺ produced by the above formulas 6 to 8 can produce Zn(NH₃)₄²⁺ and Zn(OH)₄²⁻, which are the growth factors of the ZnO nanorods, by the following formulas 9 and 10.

Zn²⁺+4NH₃→Zn(NH₃)₄²⁺ [Formula 9]

Zn²⁺+4OH⁻→Zn(OH)₄²⁻ [Formula 10]

The growth factor, Zn(NH₃)₄²⁺, produced by the above formula 9 can produce the ZnO nanorods represented by the following formula 11 by the reaction with OH⁻ as a reaction factor, and the growth factor, Zn(OH)₄²⁻, produced by the above formula 10 can produce the ZnO nanorods by the following formula 12.

Zn(NH₃)₄²⁺+2OH⁻→ZnO+4NH₃+H₂O [Formula 11]

Zn(OH)₄²⁻→ZnO+H₂O+2OH [Formula 12]

However, when the cationic polymer as the second growth inhibitor is added to the growth solution, the cationic polymer absorbs Zn(OH)₄²⁻, one of the growth factors, such that Zn(OH)₄²⁻ cannot participate in the growth of the ZnO nanoparticles. The Zn(OH)₄²⁻ is known as a factor that allows the ZnO nanoparticles to be grown in the form of an open bundle.

Therefore, the cationic polymer prevents the Zn(OH)₄²⁻ from participating in the growth of the ZnO nanoparticles, and thereby the (100) plane of the ZnO nanorods are preferentially grown along the c-axis. As a result, the ZnO nanorods can be grown on the substrate in the substantially vertical direction. These ZnO nanorods can ensure the shortest path of electron transfer, thereby increasing the electron transfer rate.

In addition, it is possible to form a single ZnO nanorod in each hole of the pattern layer 14 by adjusting the concentration of the cationic polymer. For example, the cationic polymer may be added in an amount of 0.5 to 1 M with respect to 1 M of the second zinc salt.

Meanwhile, the growth solution may have a pH of 9 to 11. When the growth solution has a pH above 11, the ZnO nanorods may be damaged by excessive corrosion. Therefore, the growth solution may have a pH of 10. For this purpose, an alkaline solution such as ammonia water may be added to the growth solution.

The OH excessively contained in the growth solution may corrode the ZnO nanorods already formed, thereby producing corrosion of Zn(OH)₂. The corrosion may be carried out along the (110) plane. As a result, each of the ZnO nanorods may have a pointed end.

ZnO+3OH⁻→Zn(OH)₂+H₂O [Formula 13]

However, the growth reaction of the ZnO nanoparticles represented by the above formula 13 may continue along with the corrosion reaction. Referring to formula 13, the OH is consumed while the ZnO nanoparticles are grown, and thereby the pH of the growth solution may be reduced. As a result, the growth reaction preferentially occurs rather than the corrosion reaction such that the ZnO nanorods below the pointed end are continuously grown, which results in the production of ZnO nanorods with a pointed end.

The thus produced ZnO nanorods with pointed ends may be applied to a laser diode in terms of optical properties.

Referring to FIG. 1D, the pattern layer 14 may be removed by wet etching using an etching solution or by dry etching using an etching gas. In the case where the pattern layer 14 is a resist layer, the etching gas may be Ar/O₂ or He/O₂, and the etching solution may be acetone.

When the second growth inhibitor is added during the growth of the ZnO nanorods, the ZnO nanorods may be preferentially grown along the c-axis. Therefore, the ZnO nanorods can ensure the shortest path of electron transfer, thereby increasing the electron transfer rate.

Moreover, it is possible to form a single ZnO nanorod in each hole of the pattern layer 14 by adjusting the concentration of the second growth inhibitor. As a result, it is possible to control the distance between ZnO nanorods and the alignment of the ZnO nanorods.

### Preparation Example 1

### Preparation of ZnO Nanoparticles

A sapphire substrate was used as a substrate, which was washed with

IPA and distilled water alternately for 10 minutes before use. ZnO nanoparticles were prepared by a hydrothermal synthesis method.

In detail, a growth solution containing a first zinc salt solution, a first precipitation solution, and a first growth inhibitor was prepared in a flask while the temperature of a thermostat was maintained at 70° C. The first zinc salt solution was prepared by mixing Zn(Ac)₂.2H₂O (98%, ACS Reagent) and alcohol, and the first precipitation solution was prepared by mixing LiOH (98%, ACS Reagent) and alcohol. As the first growth inhibitor, branched polyethyleneimine (PEI) was used.

Heat is applied to the growth solution at a temperature of 90° C. for 2 hours to prepare ZnO nanoparticles.

The ZnO nanoparticles were separated from the growth solution by centrifugation, washed with alcohol, and then dried at a temperature of 70° C.

### Preparation Example 2

### Preparation of ZnO Nanorods

A ZnO seed layer was formed by dispersing the ZnO nanoparticles prepared in the same manner as Preparation Example 1 in a mixed solution of alcohol and distilled water and spin-coating the resulting solution on a sapphire substrate.

Subsequently, a resist pattern having a plurality of holes was formed on the sapphire substrate on which the ZnO seed layer was formed. The resist pattern was formed by nano-imprinting.

A growth solution containing a second zinc salt solution, a second precipitation solution, and a second growth inhibitor was prepared. The second zinc salt solution was prepared by mixing 0.06 M of Zn(NO₃)₂.H₂O (purity: 99.5%, Aldrich Chemical Co., Ltd.) and alcohol, and the second precipitation solution was prepared by mixing 0.06 M of C₆H₁₂N₄ (purity: 99.5%, 98%, Aldrich Chemical Co., Ltd.) and alcohol. As the second growth inhibitor, 0.03 M of polyethyleneimine (PEI) was used.

The sapphire substrate on which the resist pattern having the plurality of holes was formed was immersed into the growth solution and maintained under vacuum at a temperature of 90° C.

### Preparation Example 3

This example was performed in the same manner as Preparation Example 2, except that 0.06 M of PEI was added as the second growth inhibitor.

### Preparation Example 4

This example was performed in the same manner as Preparation Example 2, except that 0.09 M of PEI was added as the second growth inhibitor.

### Preparation Example 5

This example was performed in the same manner as Preparation Example 2, except that 0.12 M of PEI was added as the second growth inhibitor.

### Comparative Example 1

This example was performed in the same manner as Preparation Example 2, except that the second growth inhibitor was not added to the growth solution.

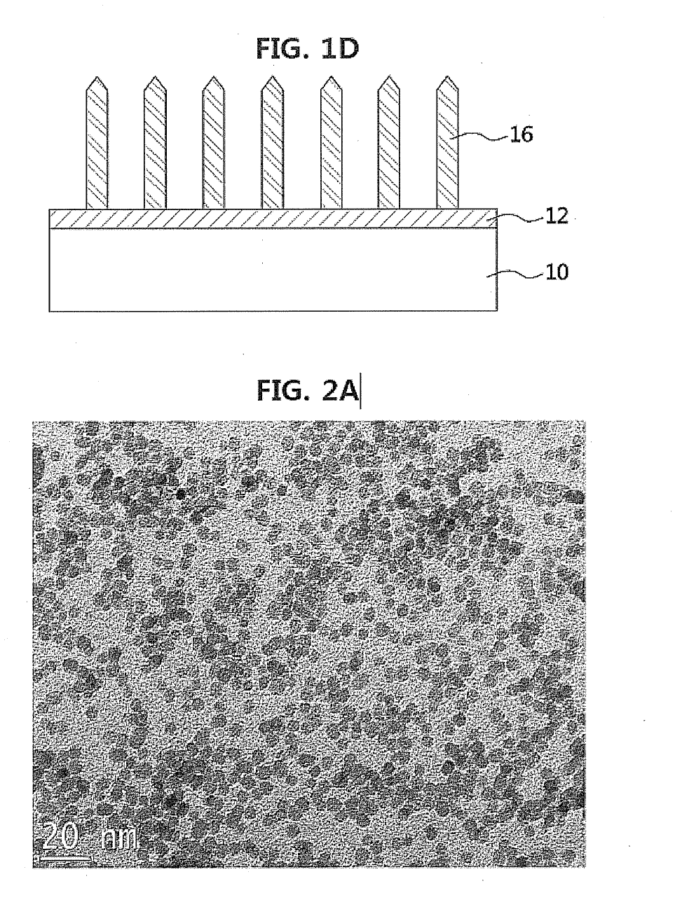

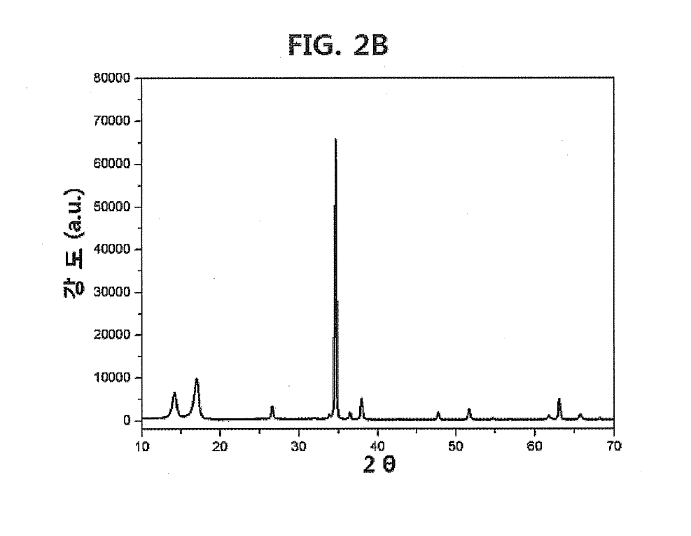

FIG. 2A is an SEM image of the ZnO nanoparticles prepared in Preparation Example 1, and FIG. 2B is an XRD graph of the ZnO nanoparticles prepared in Preparation Example 1.

Referring to FIGS. 2A and 2B, the conventional ZnO nanoparticles have an elongated shape, and thus, when they are used as a seed layer, it is difficult to form the ZnO nanorods having a uniform shape. However, it can be seen from FIG. 2A that the ZnO nanoparticles prepared in Preparation Example 1 had a uniform circular shape.

Moreover, the thus prepared ZnO nanoparticles showed a peak at 35° from the (002) direction, and thus, when the ZnO nanoparticles are used as a seed layer, the growth along the c-axis may be facilitated (FIG. 2B).

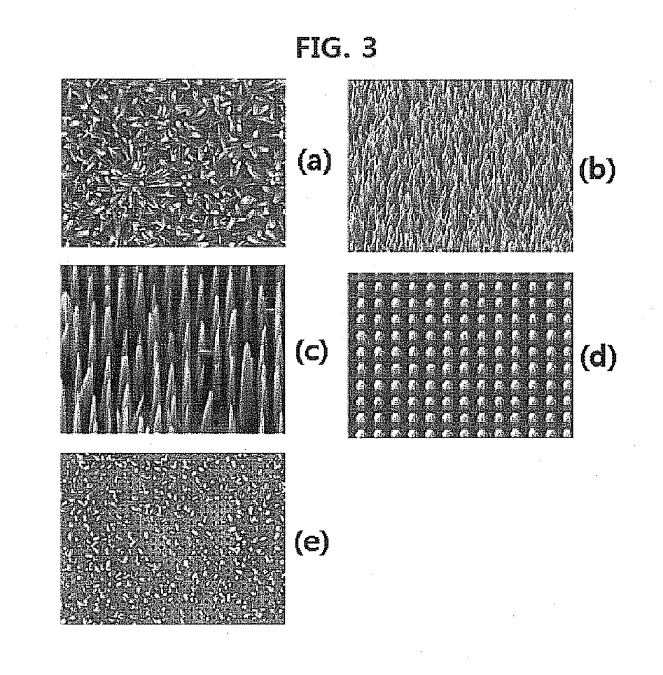

FIG. 3 shows SEM images of ZnO nanorods prepared in Preparation Examples 1 to 5 and Comparative Example 1.

Referring to FIG. 3, it can be seen that when the second growth inhibitor was not added (Comparative Example 1), the ZnO nanorods were not grown along the c-axis but grown in the form of an open bundle as shown in (a) of FIG. 3.

When 0.03 M of the second growth inhibitor was added (Preparation Example 2), the ZnO nanorods were grown along the c-axis. However, it can be seen that a single ZnO nanorod was not formed in each hole of the resist pattern, but a plurality of ZnO nanorods were formed in each hole of the resist pattern as shown in (b) of FIG. 3.

When 0.06 M of the second growth inhibitor was added (Preparation Example 3), the ZnO nanorods were grown along the c-axis and, although a plurality of ZnO nanorods were not formed uniformly in each hole of the resist pattern, a plurality of ZnO nanorods were formed partially in each hole of the resist pattern as shown in (c) of FIG. 3.

Meanwhile, when 0.09 M of the second growth inhibitor was added (Preparation Example 4), the ZnO nanorods were grown along the c-axis, and a single ZnO nanorod was formed uniformly in each hole of the resist pattern as shown in (d) of FIG. 3.

Moreover, when 0.12 M of the second growth inhibitor was added (Preparation Example 5), the second growth inhibitor inhibited the growth of the ZnO nanorods, and thus it was difficult to form the ZnO nanorods having a uniform shape as shown in (e) of FIG. 3.

Therefore, the second growth inhibitor may be added in an amount of 0.09 M.

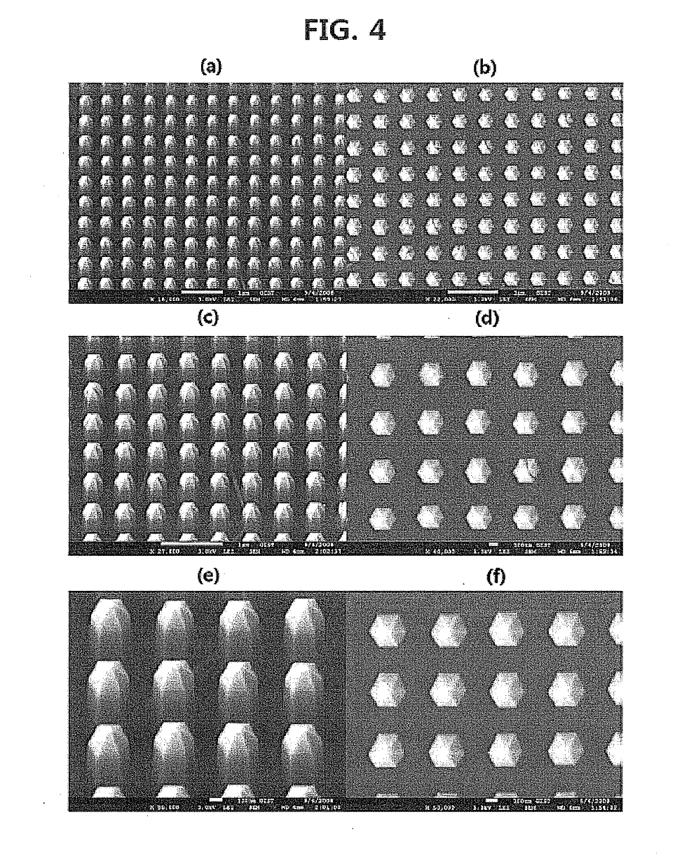

FIG. 4 shows SEM images of ZnO nanorods prepared in Preparation Example 4.

Referring to FIG. 4, the ZnO nanorods may have a hexagonal prism shape as wurtzite hexagonal structure. However, the conventional ZnO nanorods may have a circular cross-section due to its non-uniform seed layer and because the ZnO nanorods are not grown along the c-axis.

The ZnO nanorods prepared in Preparation Example 4 of the present invention have a uniform diameter and a hexagonal cross-section, not a circular cross-section. Therefore, according to the ZnO nanorods prepared in Preparation Example 4 of the present invention, it is possible to prepare ZnO nanorods preferentially grown along the c-axis with the use of the uniform seed layer and the second growth inhibitor.

The ZnO nanorods uniformly grown along the c-axis may be arranged substantially vertical to the substrate. Therefore, it is possible to ensure the shortest path of electron transfer, thereby increasing the electron transfer rate.

The ZnO nanorods having the above characteristics may be used in various fields such as organic/inorganic solar cells, organic/inorganic LEDs, etc.

As described above, according to the present invention, it is possible to prepare the ZnO nanoparticles having a uniform shape with the use of the growth inhibitor. Therefore, when the ZnO nanorods are grown on the seed layer formed with the ZnO nanoparticles, it is possible to improve the uniformity of the ZnO nanorods.

Moreover, with the addition of the second growth inhibitor, the ZnO nanorods can be grown along the c-axis. Therefore, the ZnO nanorods ensure the shortest path of electron transfer, thereby increasing the electron transfer rate.

Furthermore, it is possible to form a single ZnO nanorod in each hole of the pattern layer by adjusting the concentration of the second growth inhibitor. Thus, it is possible to control the distance between the ZnO nanorods and alignment of the ZnO nanorods.

As above, preferred embodiments of the present invention have been described and illustrated, however, the present invention is not limited thereto, rather, it should be understood that various modifications and variations of the present invention can be made thereto by those skilled in the art without departing from the spirit and the technical scope of the present invention as defined by the appended claims.

What is claimed is:

1. A method for preparing zinc oxide (ZnO) nanoparticles, the method comprising:
preparing a growth solution containing a zinc salt, a precipitator, and a growth inhibitor; and
applying heat to the growth solution to prepare ZnO nanoparticles.

2. The method of claim 1, wherein the zinc salt is zinc acetate, zinc nitrate, zinc sulfate, or zinc chloride.

3. The method of claim 1, wherein the precipitator is NaOH, Na2CO₃, LiOH, H₂O₂, KOH, or NH₄OH.

4. The method of claim 1, wherein the growth inhibitor is a cationic polymer.

5. The method of claim 4, wherein the growth inhibitor has a hyperbranched structure.

6. The method of claim 4, wherein the growth inhibitor is a polymer having an amine group.

7. The method of claim 6, wherein the growth inhibitor is polyethyleneimine.

8. A method for preparing zinc oxide (ZnO) nanorods, the method comprising:
forming a ZnO seed layer on a substrate;
forming a pattern layer including a plurality of holes on the ZnO seed layer;
preparing a growth solution containing a zinc salt, a precipitator, and a growth inhibitor; and
immersing the substrate including the pattern layer in the growth solution such that the ZnO nanorods are grown in the holes.

9. The method of claim 8, wherein the ZnO seed layer is formed by producing ZnO nanoparticles by a hydrothermal synthesis method, a sol-gel method, or a reduction method and spin-casting the ZnO nanoparticles.

10. The method of claim 8, wherein the ZnO seed layer is formed by metal, organic chemical vapor deposition (MOCVD), evaporation, or sputtering.

11. The method of claim 8, wherein the zinc salt is Zn(NO₃)₂.H₂O, C₄H₆O₄Zn.2H₂O, or ZnSO₄.7H₂O.

12. The method of claim 8, wherein the precipitator is C₆H₁₂N₄, NaOH, or KOH.

13. The method of claim 8, wherein the growth inhibitor is a cationic polymer.

14. The method of claim 8, wherein the growth inhibitor has a hyperbranched structure.

15. The method of claim 14, wherein the growth inhibitor is a polymer having an amine group.

16. The method of claim 15, wherein the growth inhibitor is polyethyleneimine.

17. The method of claim 8, wherein the growth inhibitor is added in an amount of 0.5 to 1 M with respect to 1 M of the zinc salt.

18. The method of claim 8, wherein the growth solution has a pH of 9 to 11.
